(19) United States
(12) Patent Application Publication
(10) Pub. No.: US 2020/0256730 A1
(43) Pub. Date: Aug. 13, 2020

(54) BROADBAND SEMICONDUCTOR-BASED UV LIGHT SOURCE FOR A SPECTRAL ANALYSIS DEVICE

(71) Applicant: Heraeus Noblelight GmbH, Hanau (DE)

(72) Inventors: Christoph SÖLLER, Hanau (DE); Torsten JENEK, Obertshausen (DE)

(21) Appl. No.: 16/647,512

(22) PCT Filed: Aug. 22, 2018
(86) PCT No.: PCT/EP2018/072602

§ 371 Date: Mar. 15, 2020

(30) Foreign Application Priority Data
Sep. 21, 2017 (DE) 102017121889.0

(51) Int. Cl. G01J 3/10; H01L 33/50; F21K 9/61; F21K 9/64; F21K 9/68; F21K 9/69

(52) U.S. Cl. CPC G01J 3/10; H01L 33/502; H01L 33/505; H01L 33/507; G01J 3/0218; F21K 9/64; F21K 9/68; F21K 9/69; F21K 9/61

(57) ABSTRACT

A semiconductor-based UV light source for a spectral analysis device is provided. The semiconductor-based UV light source includes a housing, in which at least one semiconductor-based emitter for emitting UV light is accommodated, and in which a beam path is formed between the semiconductor-based emitter and a beam exit point for a working beam. To provide a light source having a semiconductor-based emitter which is capable of covering at least a majority of the UV spectrum of 200 to 400 nm with its emission, the semiconductor-based emitter is designed to emit UV excitation light having an average wavelength in the range of 150 to 270 nm, and that a phosphor be provided in the beam path, which partially absorbs the UV excitation light and emits a phosphor radiation in such a way that UV excitation light and phosphor radiation are overlaid to form a working beam, which has a spectral bandwidth of at least 50 nm in the wavelength range of 200 to 400 nm.

### CROSS REFERENCE TO RELATED APPLICATIONS

This application is a U.S. national phase filing of International Patent Application Number PCT/EP2018/072602 filed Aug. 22, 2018 that claims the priority of German Patent Application Number 102017121889.0 filed Sep. 21, 2017. The disclosures of these applications are hereby incorporated by reference in their entirety.

The invention relates to a semiconductor-based UV light source for a spectral analysis device, having a housing, in which at least one semiconductor-based emitter for emitting UV light is accommodated, and in which a beam path is formed between the semiconductor-based emitter and a beam exit side for a working beam.

### BACKGROUND

Light sources, which have been established for decades, for spectral analyses in the UV range, such as xenon flash lamps and deuterium lamps, emit UV radiation in the range of approximately 200 nm to 400 nm. Both lamp types require special ballast devices for ignition and operation, in order to generate the required voltages of up to several hundred volts. In particular in the case of deuterium lamps, as a result of its relatively low efficiency in the per thousand range during operation, nearly all of the input power of typically 30 W is to be dissipated in the form of heat. The typical operating temperature of deuterium lamps is therefore in the range of 250 to 300° C. Lamps and electronics accordingly require a device size and power consumption which restrict the possible uses and mobility.

In contrast thereto, semiconductor-based light sources, for example, light-emitting diodes (LEDs) and laser diodes, open up new, more flexible possible uses, for example, in portable and thus location-independent analysis devices, due to the small size, compact power supply, and higher efficiency thereof. LEDs have in the meantime become producible and commercially available, in addition to the near infrared (NIR; typically 780 to 1100 nm) and visible (VIS; 380 to 780 nm) range of the electromagnetic spectrum, also having various emission wavelengths between approximately 230 to 400 nm in the ultraviolet (UV) range. Inter alia, this opens up the option of using them as light sources in UV-sensitive analysis and monitoring methods, for example, in high-performance liquid chromatography (HPLC), UV/VIS spectroscopy, environmental analysis, or also molecular spectroscopy.

Because of the limited spectral full width at half maximum thereof around the central emission wavelength thereof of typically between approximately 10 and 30 nm, individual LEDs in analytics applications are only suitable for detections and inspections within a correspondingly limited wavelength range. This is possibly sufficient if the analysis sample is exclusively to be tested in a targeted manner for specific, known compounds or properties. The LED wavelength can then be selected a priori according to these known data. In the case of unknown samples or complex questions, however, only measurements over a significantly broader spectral range often supply the required items of information for a sample evaluation.

LEDs of multiple wavelengths have heretofore been combined to generate a broader spectrum in the UV-A, UV-B, and UV-C range of 200 to 400 nm. Thus, for example, in US 2011/0132077 A1, such a combination of LEDs of different wavelengths is described for generating a broadband spectrum for high-performance liquid chromatography, wherein the LEDs are arranged in such a way that the emitted light beams are incident at a specific angle on a diffraction grating arrangement in dependence on the wavelength thereof, and are diffracted therein to form a common output light beam. The output light beam can thus be generated or formed having a desired spectral composition or a desired spectral profile.

Another broadband UV-LED light source based on eight LEDs having middle emission wavelengths from 250 to 355 nm (in intervals of 15 nm) is described in the paper: Kraiczek et al., “ULTRA HIGH FLEXIBLE UV-VIS RADIATION SOURCE AND NOVEL DETECTION SCHEMES FOR SPECTROPHOTOMETRIC HPLC DETECTION”, 17th International Conference on Miniaturized Systems for Chemistry and Life Sciences (27-31 Oct. 2013), Freiburg, Germany.

### SUMMARY

To continuously cover the wavelength range from approximately 250 to 400 nm, however, at least 10 LEDs are required (proceeding from a bandwidth of 15 nm). This not only increases the device costs, but rather additionally requires emission spectra adapted to one another and a complex device construction. Since in general a point light source is required in spectral analysis devices, the individual spectra have to be combined in a beam path. In addition, the stability of the emission spectrum is to be ensured in different operating conditions over the device lifetime.

So-called quantum dots represent a further known, but also complex technology for converting UV light into higher wavelength ranges.

A light source having a semiconductor-based emitter, for example, a light-emitting diode, which is capable of covering at least a majority of the UV spectrum from 200 to 400 nm with its emission, would be desirable. It would combine the advantages of the LEDs with respect to size and operation with the broadband spectrum of a classic deuterium lamp.

According to an exemplary embodiment of the invention, a semiconductor-based UV light source for a spectral analysis device is provided. The semiconductor-based UV light source includes a housing in which at least one semiconductor-based emitter for emitting UV light is accommodated, and in which a beam path is formed between the emitter and a beam exit point for a working beam. The semiconductor-based emitter is designed to emit excitation light having an average wavelength in the range of 150 to 270 nm, in that a phosphor is provided in the beam path, which partially absorbs the excitation light and emits a phosphor radiation in such a way that the excitation light and phosphor radiation are overlaid to form a working beam which has a spectral bandwidth of at least 50 nm in the wavelength range of 200 to 400 nm.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 illustrates a first embodiment of a semiconductor-based UV light source having a phosphor applied to an LED housing according to an exemplary embodiment of the invention;

FIG. 2 illustrates a second embodiment of a semiconductor-based UV light source having a phosphor contained in an LED housing according to an exemplary embodiment of the invention;

FIG. 3 shows a third embodiment of a semiconductor-based UV light source having a phosphor applied to an end face of an optical fiber according to an exemplary embodiment of the invention;

FIG. 4 shows a fourth embodiment of a semiconductor-based UV light source having a phosphor applied to the inner wall of a capillary borehole according to an exemplary embodiment of the invention;

FIG. 5 shows a fifth embodiment of a semiconductor-based UV light source having a quartz glass substrate positioned in the beam path and phosphor applied thereon according to an exemplary embodiment of the invention;

FIG. 6 shows the emission spectrum of an LED having a maximum of the emission at 256 nm according to the prior art;

FIG. 7 shows the emission spectrum of an LED of FIG. 6 upon use in a semiconductor-based UV light source as shown in FIG. 1 and in combination with a first phosphor according to an exemplary embodiment of the invention; and

FIG. 8 shows the emission spectrum of an LED of FIG. 6 upon use in a semiconductor-based UV light source as shown in FIG. 5 and in combination with a second phosphor according to an exemplary embodiment of the invention.

### DETAILED DESCRIPTION

This object is achieved according to exemplary embodiments of the invention, proceeding from a semiconductor-based UV light source of the type mentioned at the outset, in that the semiconductor-based emitter is designed for emitting UV excitation light having an average wavelength in the range of 150 to 270 nm, a phosphor is provided in the beam path, which partially absorbs the UV excitation light and emits a phosphor radiation in this case, in such a way that UV excitation light and phosphor radiation are overlaid to form a working beam, which has a spectral bandwidth of at least 50 nm in the wavelength range of 200 to 400 nm.

Spectral bandwidth refers here and hereafter to the wavelength span, over which the radiation flux is at least 10% of the maximum value of the distribution.

In the UV light source according to the invention, a semiconductor-based UV emitter is combined with one phosphor or with multiple different phosphors. The phosphor or the phosphors are contained, for example, in one layer or in multiple layers. Instead of one UV emitter, multiple UV emitters can also be provided, which are embodied as a so-called “array”. The UV emitter is preferably a light-emitting diode (LED) or a laser.

The phosphor is capable of luminescence upon excitation by the UV excitation light of the semiconductor-based emitter, and the UV excitation light, at an average wavelength in the range of 150 to 270 nm, particularly preferably at an average wavelength in the range of 200 to 270 nm, is in the excitation wavelength range of the phosphor. It is arranged within the beam path, so that it is irradiated by the UV excitation light. A part of the shortwave UV excitation light from the wavelength range of 150 to 270 nm is absorbed in this case and converted by the phosphor into longer-wave phosphor radiation in the UV-A, UV-B, and/or UV-C-FUV. The wavelength range from 315 to 400 nm is typically defined as the UV-A range, the wavelength range from 280 to 315 nm as the UV-B range, and the wavelength range from 200 to 280 nm as the UV-C-FUV range.

The quantity and distribution of the phosphor in the beam path are designed in such a way that the UV excitation light is not completely absorbed therein, so that a part of the UV excitation light passes through the beam path unchanged to the beam exit point. By way of the superposition of this UV light beam with the emitted phosphor radiation, a working beam is obtained, the overall spectrum of which in the UV wavelength range of 200 to 400 nm has a spectral bandwidth of at least 50 nm, preferably a spectral bandwidth of at least 100 nm, and thus covers a large part of the combined UV-A, UV-B, and UV-C-FUV range, and which preferably comprises at least the wavelength range from 260 to 310 nm.

The UV excitation light is used for generating working radiation having broadband wavelength spectrum. The spectral contribution of the UV excitation light to the spectral bandwidth of the working radiation is comparatively small, however, and is preferably less than 50%. The ratio of the spectral bandwidth of the UV excitation light to the overall bandwidth of the working radiation is understood here as the “spectral contribution”. The term “spectral bandwidth” again refers to the width of the wavelength-dependent radiant flux curve at which the radiant flux has dropped to 1/10 of the maximum value.

To generate the most broadband working radiation possible, a large-fraction energetic conversion of the UV excitation light into phosphor radiation is advantageous. An embodiment of the semiconductor-based UV light source is therefore preferred in which quantity and distribution of phosphor in the beam path are set in such a way that the fraction of the UV excitation light in the overall radiant flux of the working beam is less than 50% and is preferably in the range of 5 to 35%.

The fraction of the UV excitation light which is absorbed by the phosphor is dependent on the type, quantity, and distribution of the phosphor in the beam path. The phosphor can be provided at one point or at multiple points in the beam path. The shortwave UV excitation light can be incident on the phosphor to bring it to luminescence and is partially transmitted by the phosphor.

In one advantageous embodiment of the semiconductor-based UV light source according to the invention, in which the phosphor is introduced into the beam path in the form of a phosphor-containing layer, the UV excitation light is partially transmitted by the phosphor-containing layer.

Neglecting possible scattering or reflection fractions, the phosphor does not have a completely absorbing or scattering effect on the UV excitation light, depending on the layer thickness, so that the remaining fraction of non-absorbed UV excitation light can easily be predetermined via the setting of the phosphor layer thickness to be passed. The average phosphor layer thickness is typically in the range between 5 to 100 μm, the thickness range is particularly preferably between 5 and 30 μm. Low layer thicknesses of the phosphor-containing layer ensure that the UV excitation light is not completely absorbed therein, but rather a part can pass the phosphor-containing layer unchanged.

The semiconductor-based UV light source according to the invention is designed for use in a spectral analysis device. High-precision beam guiding having the least possible beam divergence and small fraction of directed or diffuse scattering is desired for this purpose.

A particularly preferred embodiment of the UV light source is therefore distinguished in that one or more means for guiding the excitation light and/or the working beam are provided between the emitter and the beam exit side.

In particular UV LEDs can have emission angles (at 50% of the maximum value) of 120° or more. With regard to a small widening of the beam diameter already at the beginning in the region between the UV light-emitting diode and the phosphor, an embodiment of the semiconductor-based UV light source is preferred in which the least possible distance lies between UV light-emitting diode and phosphor or in which means for beam guiding are arranged in the intermediate space of UV light-emitting diode and phosphor.

In an embodiment which is particularly suitable in this aspect, the semiconductor-based emitter includes an exit surface for the UV excitation light, and the phosphor-containing layer includes an entry surface for the UV excitation light, wherein the shortest distance between exit surface and entry surface is less than 5 mm.

In the simplest and most favorable case, the exit surface for the UV excitation light and the entry surface of the phosphor-containing layer directly adjoin one another. Little to no widening of the UV excitation light beam thus results.

Advantageous and high-precision beam guiding is also achieved, however, if the exit surface is spaced apart from the entry surface, and the distance is less than 5 mm.

As a result of scattering, the working beam emitted from the phosphor-containing layer can also have a certain angle distribution. With regard to this, it has proven itself if one or more means for guiding the working beam are provided between the phosphor-containing layer and the beam exit side.

For example, optical lenses, reflectors, fibers, or capillaries are suitable as the means for guiding the working beam.

The following embodiments of the semiconductor-based UV light source in combination with a phosphor-containing layer have proven to be advantageous:
Embodiments in which the semiconductor-based emitter includes an emitter housing having an exit window for the UV light beam, which is coated by a phosphor-containing layer.
Embodiments in which the semiconductor-based emitter includes an emitter housing into which the phosphor is introduced as a powder or as a casting material.
Embodiments in which the beam exit side is formed as an exit opening and is covered using a window made of a UV-transmissive material, which is coated by a phosphor-containing layer, wherein the window closing the beam exit side can be embodied here in particular as a condenser lens.
Embodiments in which the beam path is at least partially formed by an optical fiber, wherein the phosphor is applied to at least one of the end faces of the optical fiber. The optical fiber can begin at the beam exit side, for example: it can end there or it can be led out of the housing from the beam exit side. The optical fiber has a core and a jacket enclosing the core. The light guiding in the core is known to be based on total reflection on the jacket. The UV excitation light coupled into the core and/or the working radiation coupled into the core can be conducted with high precision to the beam exit point without noticeable losses due to damping and scattering as a result of the light guiding.
Embodiments in which a phosphor-containing layer is applied to a UV-transparent carrier, which is arranged between the semiconductor-based emitter and the beam exit point and is transmissive to the UV excitation light and to the working beam. The UV-transparent carrier is generally embodied as plate-shaped, wherein the phosphor-containing layer is formed on the plate surface facing toward the light-emitting diode and/or on the opposing plate surface. The material-specific transmissivity of the carrier, for example, a glass, for the UV excitation light and for the working beam is defined in this case as a transmittance of at least 70%/mm.

In another advantageous embodiment of the UV light source according to the invention, the phosphor is arranged as a phosphor-containing layer in the beam path in such a way that UV excitation radiation is reflected and/or scattered.

The phosphor-containing layer absorbs in this case a part of the UV excitation radiation which is reemitted as longer-wave radiation and it reflects a part of the UV excitation radiation either directly on its layer surface or on the surface of a substrate to which the phosphor-containing layer is applied. The fraction reemitted as longer-wave radiation and the reflected fraction of the UV excitation radiation form the working beam.

In this embodiment of the semiconductor-based UV light source according to the invention, it has proven to be advantageous, for example, if the beam path extends at least partially through the cavity of a capillary or a hollow core fiber, wherein the phosphor is contained in the capillary or fiber cavity.

The UV excitation beam extends in this case in the direction of the capillary or fiber longitudinal axis, wherein the phosphor can completely or partially fill up the capillary or fiber cavity or can only be provided on the cavity wall. The cavity wall can be used in this case as a substrate for the phosphor-containing layer, which reflects the UV excitation radiation. The phosphor-containing layer necessarily causes a certain scattering of the UV excitation radiation and the emitted longer-wave radiation. In this embodiment of the semiconductor-based UV light source, the scattered light fraction is guided in the capillary or fiber cavity to the light exit side, so that little useful light is lost.

In particular for tanning lamps, phosphors emitting in the UV-A range and UV-B range are known, for example, lead-activated barium disilicate (BaSi₂Os:Pb) having an emission maximum at 351 nm, and europium-activated strontium borate (SrB₄O₇:Eu) having an emission maximum at 371 nm, by means of which, in combination with other phosphors such as CeMgAl₁₁O₉, LaPO₄:Ce, and (Sr,Ba)MgSi₂O₇:Pb, the specification parameters of the tanning lamps are set in such a way that an approximation to a specific desired emission spectrum in the ultraviolet spectral range results.

Further known phosphors of this type are, for example, cerium-activated strontium-magnesium-aluminate (Sr(Al,Mg)₁₂O₁₉:Ce) having an emission maximum at 306 nm and cerium-activated yttrium phosphate (YPO₄:Ce).

The coating of the radiator jacket, which is typically over a large area because of its intended use, with a phosphor and the correspondingly large emission surface make this radiator type unsuitable for analysis devices, however, in which in general point-like light sources are advantageous. The phosphors used in this case are fundamentally also suitable for the present application, however, if they can be excited by UV radiation in the wavelength range of 150 to 270 nm for emission in the wavelength range of 200 to 400 nm.

Moreover, a phosphor is preferably used in the semiconductor-based UV light source according to the invention, the excitation wavelength of which is in the range of 200 to 270 nm and which has the broadest possible emission spectrum. A phosphor has proven itself in regard thereto which is a cerium-doped mixed oxide, and which preferably contains strontium-magnesium aluminate, yttrium phosphate, and/or gadolinium phosphate.

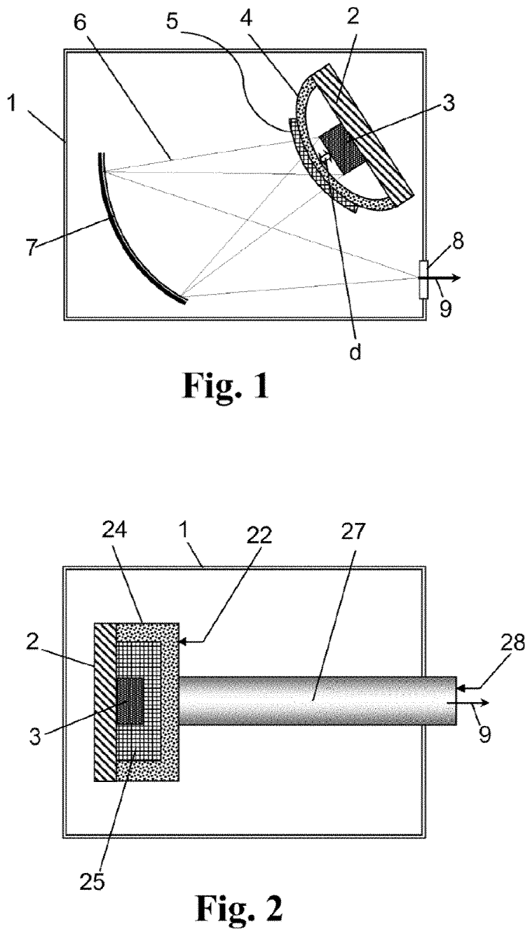

Exemplary embodiments of the invention are explained in greater detail hereafter on the basis of exemplary embodiments and drawings, including as shown in FIGS. 1-8.

The embodiment of the UV LED light source according to the invention shown in a schematic illustration in FIG. 1 includes a lamp housing 1 consisting of aluminum, into which an LED 3 installed on a circuit board 2 is inserted. The LED 3 emits UV light having a main emission line at a wavelength of 256 nm. It is enclosed by a cupola-shaped cover 4 made of quartz glass, on the outer surface of which a layer 5 made a phosphor having an average layer thickness of 15 μm is applied (the thickness is not to scale for reasons of illustration).

The UV radiation 6 emitted by the LED 3 passes the phosphor layer 5, is partially absorbed in this case and converted into longer-wave radiation, and reaches, via a focusing reflector 7, a beam exit window 8 of the housing 1, which it leaves as emitted working radiation 9. The working radiation 9 contains a first radiation fraction from the wavelength range of the UV excitation radiation 6 emitted by the LED 3 and a second radiation fraction from the longer-wave wavelength range, which is emitted by the phosphor.

The maximum distance “d” between the light exit surface of the LED 3 and the phosphor-containing layer 5 is 2 mm. The focusing reflector 7 is used simultaneously as means for high-precision beam guiding.

In a modification of the embodiment shown in FIG. 1, the phosphor layer 5 is applied having a layer thickness of 15 μm to the inner side of the light exit window 8, additionally or alternatively to the layer on the cupola-shaped cover 4.

FIGS. 1-5 show various embodiments of the UV-LED light source according to the invention. Identical or equivalent components and component parts are each identified with the same reference signs in this case.

In the embodiment of the UV-LED light source according to the invention illustrated in FIG. 2, the LED 3 installed on a circuit board 2 is enclosed by a housing 24, which is filled using a potting material made of UV-transparent silicone and phosphor. The potting material forms a phosphor layer 25 in the meaning of the invention. The housing 24 has a planar outer side 22, on which an optical fiber 27 is placed with one of its interfaces. The other end face of the optical fiber 27 forms the beam exit point 28 of the UV-LED light source.

The UV excitation radiation emitted by the LED 3 is partially absorbed by the phosphor potting material 25 inside the housing 24, converted in this case into longer wave radiation and reaches the beam exit point 28 via the optical fiber 27. The working radiation 9 exiting there contains a first radiation fraction from the wavelength range of the UV excitation radiation emitted by the LED 3 and a second radiation fraction from the longer wave wavelength range, which is emitted by the phosphor.

The light exit surface of the LED 3 directly adjoins the phosphor layer 25 in this case, so that the widening of the UV light beam emitted by the LED 3 up to the entry into the phosphor layer 25 is minimized. The working beam exiting from the housing 24 is guided in the core of the optical fiber 27 up to the light exit point 28. The optical fiber 27 is thus used as means for high-precision beam guiding after emission by the phosphor layer 25.

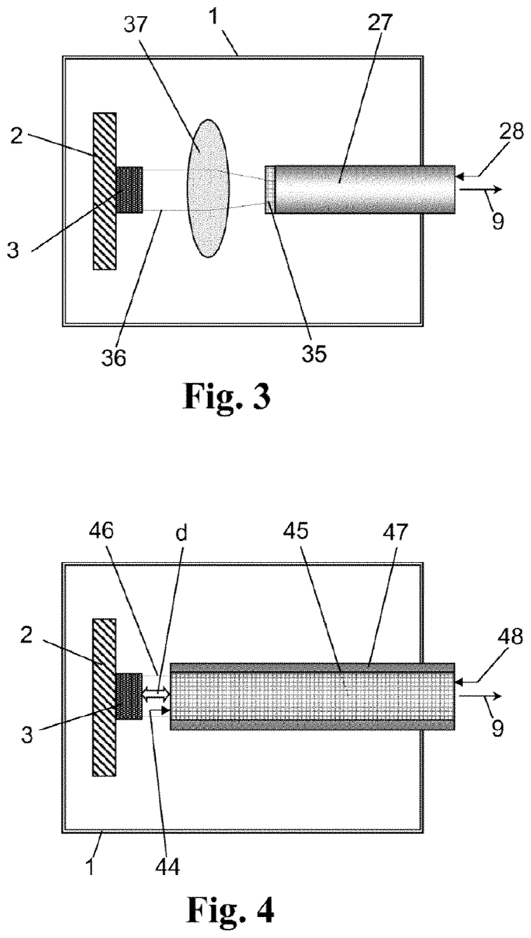

The distal end, protruding from the housing 1, of an optical fiber 27 also forms the beam exit point 28 of the UV light source in the embodiment of the UV-LED light source according to the invention according to FIG. 3. The proximal end, i.e., the end facing toward the LED 3 upon intended use, of the optical fiber 27 is coated using a phosphor layer 35 having a thickness of 25 μm. The LED is embodied as a so-called “packaged LED”, i.e., having a housing, and is installed on a circuit board 2. The emitted excitation radiation 36 is imaged by a converging lens 37 on the phosphor layer 35 and the working radiation 9 is conducted by the optical fiber 27 out of the housing 1.

The UV excitation radiation 36 emitted by the LED 3 partially penetrates the phosphor layer 35 and is converted in the other part into longer-wave radiation. The overall radiation made up of a fraction of uninfluenced UV excitation radiation 36 and a fraction of radiation modified in the phosphor layer 35 exits as working radiation 9 from the beam exit point 28.

The converging lens 37 is used as the means for high-precision beam guiding of the UV excitation beam 36 before its entry into the phosphor layer 35, and the optical fiber 27 is used as means for high-precision beam guiding of the working beam after exit from the phosphor layer 35.

In the embodiment of the UV LED light source according to the invention illustrated in FIG. 4, circuit board 2 and LED 3 installed thereon correspond to the embodiment of FIG. 3. The UV excitation radiation 46 is incident on the proximal end 44, i.e., the end facing toward the UV LED 3 upon intended use, of a capillary 47. The capillary cavity is filled using a phosphor, which forms a phosphor layer 45 in the meaning of the invention.

The excitation radiation 46 emitted by the UV LED 3 reaches the capillary cavity directly, interacts with the phosphor fixed in the phosphor layer 45, and exits as working radiation 9 from the beam exit side 48, i.e., the distal end of the capillary 47, out of the housing 1. The working radiation 9 is made up of a fraction of uninfluenced UV excitation radiation 46 and a fraction of radiation modified in the phosphor layer 45.

The distance “d” between the light exit surface of the LED 3 and the frontal end 44 of a capillary 47 (i.e., the phosphor layer 45) is 4 mm.

The spectral conversion of the UV excitation radiation 46 into the working beam 9 takes place in the phosphor layer 45 inside the capillary 47. It is used as means for high-precision beam guiding of both the UV excitation beam 46 and also the working beam to the light exit point 48.

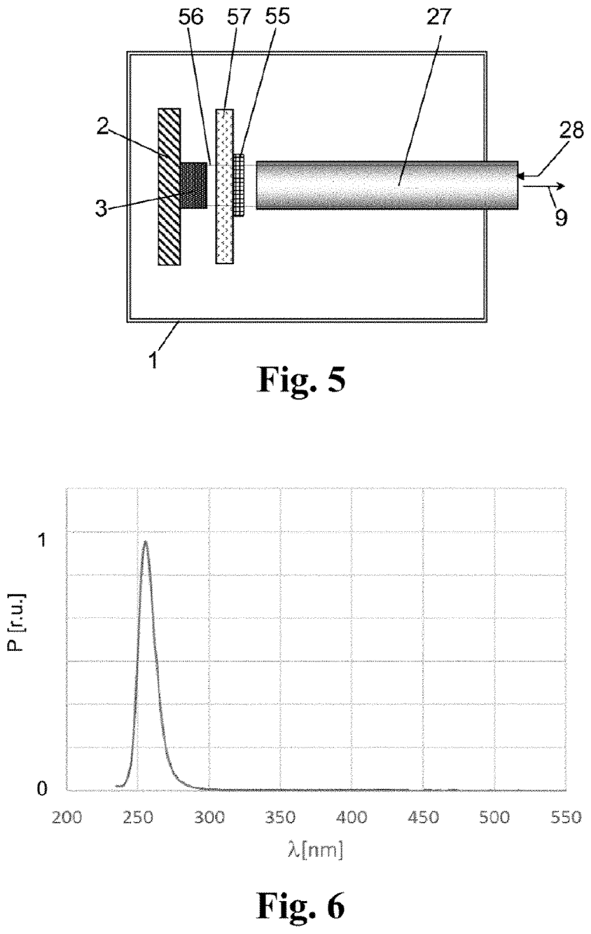

In the embodiment of the UV-LED light source according to the invention schematically illustrated in FIG. 5, circuit board 2 and LED 3 installed thereon correspond to the embodiment of FIG. 3. The distal end of an optical fiber 27 protruding out of the housing 1 forms the beam exit point 28 of the UV light source. A substrate 57 made of quartz glass having phosphor-containing layer 55 deposited thereon having a thickness of 20 μm is located between the proximal end and the LED 3 and in the beam path of the UV excitation radiation 56.

The UV excitation radiation 56 emitted by the LED 3 penetrates the substrate 57 and is partially absorbed in the phosphor layer 55 and in the other part is converted into longer-wave radiation. The overall radiation made up of a fraction of uninfluenced working radiation 56 and a fraction of radiation modified in the phosphor layer 55 exits as working radiation 9 from the beam exit point 28.

The distance “d” between the light exit surface of the LED 3 and the phosphor layer 55 is 4 mm.

The working beam exiting from the phosphor layer 55 is guided in the core of the optical fiber 27 up to the light exit point 28. The optical fiber 27 is thus used as means for beam guiding with pinpoint accuracy after emission by the phosphor layer 25.

In the emission spectra of FIGS. 6-8, the emitted radiant flux P (in relative units), scaled to the maximum value, is plotted against the wavelength λ (in nm).

FIG. 6 shows the emission spectrum of the LED 3. The emission maximum is at 256 nm and the spectral width—the wavelength range up to one tenth of the maximum value—extends from 245 to 273 nm, i.e., over a wavelength range of 28 nm.

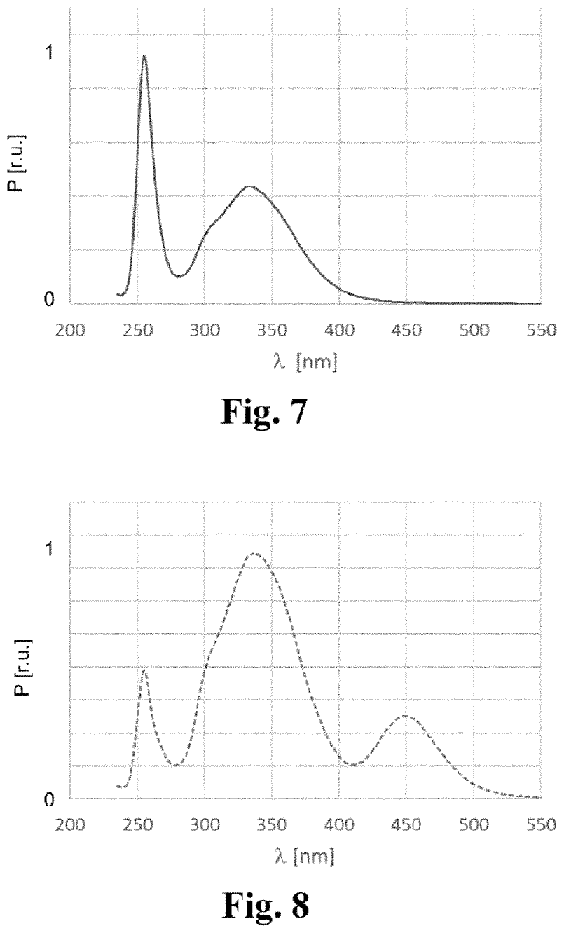

In comparison thereto. FIG. 7 shows the working radiation 9 emitted from the exit window 8 upon use of the LED 3 in combination with a first UV phosphor 5, which is embodied, as schematically shown in FIG. 1, as an external coating 5 of the cover 4 having an average layer thickness of 15 μm. The phosphor consists of cerium-doped strontium-magnesium aluminate having the molecular formula (Sr,Mg)Al₁₂O₁₉.

If one uses falling below 10% of the maximum value as the boundary of the spectral width, the total spectrum thus extends here from 245 to 390 nm, i.e., over a wavelength range of 145 nm. This corresponds to an increase in the bandwidth by more than five-fold in comparison to the emission spectrum of FIG. 6 (28 nm). The spectral contribution of the excitation light to the spectral bandwidth of the working radiation 9 is thus approximately 19% and the fraction of the UV excitation light in the overall radiant flux of the working beam 9 is approximately 32%.

FIG. 8 shows the emitted working radiation 9 upon use of the LED 3 in combination with a phosphor layer 55 made of another UV phosphor. As schematically shown in FIG. 5, it is embodied having an average layer thickness of 20 μm as a coating of a UV-transparent carrier made of quartz glass. The phosphor consists of a mixture of cerium-doped strontium-magnesium aluminate and barium-magnesium aluminate (BAM) in the ratio 9:1.

Using this phosphor, which emits over a broader wavelength range, a working radiation 9 having a spectrum of 246 to 490 nm can be achieved, i.e., more than eight-fold the bandwidth (28 nm) of the original emission spectrum of the LED 3, as shown in FIG. 6. The spectral contribution of the excitation light to the spectral bandwidth of the working radiation 9 is only still approximately 10% here.

The semiconductor-based UV light source according to the invention is therefore particularly suitable for use as a beam source in a spectral analysis device, for example, in liquid chromatography (HPLC and UHPLC), in capillary electrophoresis, and in thin-film chromatography.

1. A semiconductor-based UV light source for a spectral analysis device, the semiconductor-based UV light source comprising:
a housing in which at least one semiconductor-based emitter for emitting UV light is accommodated, and in which a beam path is formed between the semiconductor-based emitter and a beam exit point for a working beam,
wherein the semiconductor-based emitter is designed to emit excitation light having an average wavelength in the range of 150 to 270 nm, in that a phosphor is provided in the beam path, which partially absorbs the excitation light and emits a phosphor radiation in such a way that the excitation light and phosphor radiation are overlaid to form a working beam which has a spectral bandwidth of at least 50 nm in the wavelength range of 200 to 400 nm.

2. The semiconductor-based UV light source according to claim 1, wherein the working beam has a spectrum including at least the wavelength range of 260 to 310 nm.

3. The semiconductor-based UV light source according to claim 1 wherein a spectral contribution of the excitation light to the spectral bandwidth of the working radiation is less than 50%.

4. The semiconductor-based UV light source according to claim 1 wherein a quantity and distribution of phosphor in the beam path are set so that a fraction of the excitation light in a radiant flux of the working beam is less than 50%.

5. The semiconductor-based UV light source according to claim 1 wherein one or more means for guiding the excitation light and/or the working beam are provided between the semiconductor-based emitter and the beam exit point.

6. The semiconductor-based UV light source according to claim 1 wherein the phosphor is introduced into the beam path in the form of a phosphor-containing layer.

7. The semiconductor-based UV light source according to claim 6, wherein the phosphor-containing layer partially transmits the excitation light.

8. The semiconductor-based UV light source according to claim 6 wherein the phosphor-containing layer has a layer thickness in the range of 5 to 100 μm.

9. The semiconductor-based UV light source according to claim 6 wherein the semiconductor-based emitter includes an exit surface for the excitation light, and in that the phosphor-containing layer includes an entry surface for the excitation light, and in that the shortest distance between exit surface and entry surface is less than 5 mm.

10. The semiconductor-based UV light source according to claim 6 wherein the semiconductor-based emitter is coated by the phosphor-containing layer and/or partially enclosed thereby.

11. The semiconductor-based UV light source according to claim 6 wherein the semiconductor-based emitter includes an emitter housing having an exit window for the excitation light which is coated using the phosphor-containing layer.

12. The semiconductor-based UV light source according to claim 6 wherein the beam exit point is formed as a light exit opening of the housing and is covered using a window made of a UV-transmissive material, which is coated using the phosphor-containing layer.

13. The semiconductor-based UV light source according to claim 6 wherein the phosphor-containing layer applied to a carrier which is arranged between the semiconductor-based emitter and the beam exit point and is transmissive to the excitation light and to the working beam, preferably having an internal transmission of at least 70% mm⁻¹.

14. The semiconductor-based UV light source according to claim 6 wherein the beam path extends at least partially through an optical fiber, and in that the phosphor-containing layer is applied to at least one of the end faces of the optical fiber.

15. The semiconductor-based UV light source according to claim 1 wherein the semiconductor-based emitter includes an emitter housing into which the phosphor is introduced.

16. The semiconductor-based UV light source according to claim 1 wherein the beam path extends at least partially through a cavity of a capillary or a hollow core fiber, and in that the phosphor is contained in the cavity.

17. The semiconductor-based UV light source according to claim 1 wherein the phosphor is arranged in the beam path in such a way that excitation radiation is reflected and/or scattered thereon.

18. The semiconductor-based UV light source according to claim 1 wherein the phosphor is a cerium-doped mixed oxide, which preferably contains strontium-magnesium aluminate, yttrium phosphate, and/or gadolinium phosphate.

19. The semiconductor-based UV light source according to claim 1 wherein the semiconductor-based emitter is a light-emitting diode (LED) or a laser, and is designed to emit the excitation light having an average wavelength in the range of 200 to 270 nm, and in that the working beam has a spectral bandwidth of at least 100 nm.
